(19) United States
(12) Patent Application Publication
(10) Pub. No.: US 2004/0055152 A1
(43) Pub. Date: Mar. 25, 2004

(54) Bonding of a multi-layer circuit to a heat sink

(76) Inventor: James Fraivillig, Boston, MA (US)

Correspondence Address: Jonathan P. Osha, ROSENTHAL & OSHA L.L.P., Suite 2800, 1221 McKinney Street, Houston, TX, 77010, US

(21) Appl. No.: 10/670,812

(22) Filed: Sep. 25, 2003

Related U.S. Application Data
(63) Continuation-in-part of application No. 10/044,604, filed on Jan. 11, 2002.
Application No. 10/044,604 is a continuation-in-part of application No. 09/225,272, filed on Jan. 5, 1999, now abandoned.

(51) Int. Cl. H05K 3/36; H05K 1/16

(52) U.S. Cl. 29/830; 29/831; 29/832; 174/260; 174/250

(57) ABSTRACT

A method for manufacturing a printed circuit bonded to a heat sink includes producing the printed circuit comprising at least one conductive layer circuit pattern laminated to at least one side of a dielectric layer; first adhering a first side of a bond film to the printed circuit, wherein the first adhering conforms the printed circuit to the bond film to substantially remove air entrapment between the printed circuit and the bond film; and second adhering a second side of the bond film to the heat sink, wherein the first adhering and the second adhering bond the heat sink to the printed circuit.

### CROSS-REFERENCE TO RELATED APPLICATIONS

This is a continuation-in-part of U.S. application Ser. No. 10/044,604, filed on Jan. 11, 2002, which is a continuation-in-part of U.S. application Ser. No. 09/225,272, filed on Jan. 5, 1999, now abandoned. The contents of these applications are hereby incorporated in their entirety.

### BACKGROUND OF INVENTION

Printed circuits may be used as a replacement for conventional wiring circuits. A printed circuit is typically smaller and easier to manufacture than a conventional round wire circuit. A typical printed circuit includes an electrically conductive layer (“a conductive layer”), such as a copper foil, that is laminated to or sandwiched between layers of dielectric insulation. The conductive layer is imaged and etched according to a particular pattern to form a circuit. The imaging and etching process is very accurate, repeatable, and allows the printed circuit to have much higher circuit density than its round wire counterpart.

One type of printed circuit is a printed circuit board (PCB). The PCB uses a flat resin-saturated glass cloth for insulation and protection. The PCB is formed from a conductive layer laminated on such a resin-saturated glass cloth. This conductive layer is imaged and etched to form a circuit pattern. The resin is typically made of a hard and rigid material such as epoxy. Such a board provides the printed circuit with a tough and durable support base.

Another type of printed circuit is a flexible printed circuit, or “flex.” The flexible printed circuit is similar to the PCB except that it has a flexible support base, instead of a rigid one. The flexible support base is typically made of a flexible, dielectric material (e.g., a polyimide or polyester film) that allows the printed circuit to be adapted to non-flat structures or to actually “flex” in the application. Typically, the flexible printed circuit includes a conductive layer (e.g., a copper foil) which is laminated to a dielectric layer.

Printed circuits (or printed circuit boards), both flex and rigid PCBs, are typically adhered to heat sinks for thermal transfer with a number of bonding technologies. Because the heat sink is electrically conductive, care must be taken to insulate the conductive layer of the printed circuit from the heat sink. Generally, electrical isolation of a copper conductive layer on the printed circuit (next to the heat sink) is provided during manufacture of the PCB, such as with a solder mask coating. Furthermore, in laminating a printed circuit to a heat sink, it is desirable to maximize the transfer of thermal energy from the conductive layer to the heat sink. To ensure efficient thermal transfer, a printed circuit should be laminated to a heat sink in a manner that minimizes air entrapment.

A number of methods are available for adhering a printed circuit to a heat sink. First, a printed circuit may be adhered to a heat sink with a pressure-sensitive adhesive layer (PSA), generally 2-5 mil thick, which may be filled with ceramic powder to enhance thermal transfer. With this approach, an adequate thickness of adhesive to encapsulate copper conductors of the circuit is required. The PSA bonds immediately and does not require special processing.

In a second method, a printed circuit may be adhered to a heat sink with an epoxy adhesive layer, generally 2-5 mil thick, which may be filled with ceramic powder to enhance thermal transfer. Again, an adequate thickness of the adhesive layer may be required to encapsulate copper conductors on the bottom of the printed circuit. A thermosetting epoxy requires pressure and heat during a cure cycle (such as 150° C. for 1-2 hours) to bond the circuit to the heat sink.

In the third method, a printed circuit may be adhered to a heat sink with a non-adhesive interface material and attachment hardware. Examples of suitable interface materials include thermal grease and phase-change material. These interface materials may be filled with ceramic powder to enhance thermal transfer. An adequate thickness of interface material is also required to encapsulate copper conductors of the circuit. Examples of using thick adhesives to encapsulate the printed circuit patterns may be found in U.S. Pat. No. 6,140,707 issued to Plepys et al. and in U.S. application Ser. No. 2001/0052647 by Plepys et al. However, the thicker adhesive layer increases the cost and reduces the efficiency of thermal transfer.

In addition to the above methods, other circuit technologies, such as insulated metal substrate (IMS) and direct bond copper (DBC), have also been used in power electronics applications where significant heat are generated and need to be dissipated through the substrate. Such electronics include, for example, power converter modules, automotive controls, solid-state relays, and multi-chip modules.

Insulated metal substrate (IMS) has etched copper conductors bonded to an aluminum base plate with an epoxy adhesive that is filled with ceramic powder for thermal transfer. In a majority of applications, thick copper foil is laminated to the aluminum base plate with B-staged ceramic-filled epoxy at high temperature and high pressure to form a laminate panel. Due to the difference in coefficient-of-thermal-expansion (CTE) between copper and aluminum metals, the laminate panel may “bow” or curl at room temperature after the laminate panel cools from the high temperature lamination process. To avoid or reduce this problem, the maximum thickness of copper foil is generally 10% of the thickness of the aluminum plate.

The copper/aluminum IMS laminates are typically imaged-and-etched in large panels to form to a plurality of the desired circuit pattern. After the etching process, these panels are then cut into individual circuits by punching or scoring the aluminum base plate. To prevent chemical attack of the aluminum base plate during the copper etching process, masking and/or special process chemicals may be applied on the aluminum base plate. Care is taken during circuit processing and installation not to damage the epoxy dielectric layer because voids or “cracks” may lead to electrical shorting between the copper conductors and the aluminum base plate. Due to process considerations in both circuit manufacturing and depanelizing, the aluminum base plates used in IMS constructions are typically no more than about 0.125 inches thick. In addition, only planar aluminum base plates may be used for IMS constructions.

To provide shielding or enhance cooling, walls and fins may be added to IMS constructions after circuit processing. For example, an aluminum heat sink with fins may be bolted to the IMS aluminum base plate to enhance cooling. Alternatively, the IMS aluminum base plate itself may be skived or formed to enhance cooling. However, these additional processes add considerable complexity to the aluminum base plate processing and considerable cost to an assembly.

Multi-layer circuitry (i.e., two or more layers) may be required in many applications with complex designs. Two-layer IMS laminates are typically made by printing and etching double sided copper conductor panels (with a ceramic-filled epoxy substrate between the two conductive layers). At areas where power electronic components are to be solder attached, plated-through thermal vias are used to connect the top and bottom conductor layers. In most applications, much of the heat passes through these metal thermal vias, rather than through the plastic and ceramic dielectric substrate layer. The double-sided panels are then laminated to the aluminum base plate with a bond layer of ceramic-filled epoxy sheet, which provides electrical isolation from, and thermal transfer to, the aluminum base plate. The final lamination can then be processed and depanelized into individual circuits.

Direct-bond copper (DBC) circuits have copper or silver conductors on ceramic wafers. Ceramic wafers, such as alumina or boron nitride, are typically used because they provide excellent dielectric strength and high thermal transfer characteristics. In DBC manufacturing, conductors are added to the ceramic wafers by screen printing and/or plating.

DBC circuits are expensive because both the ceramic materials and the processing are expensive. For example, silver ink used in screen printing may need to be cured at 1000° C., and ceramic materials are brittle and are typically processed in a size of no more than 4 inches by 4 inches. In addition, individual circuits need to be depanelized from the ceramic panel by precise scoring.

DBC wafers have very little “thermal mass.” In practically all applications, the DBC wafer is mounted with thermally conductive adhesive, hardware, and/or interface material to an aluminum heat sink.

Multi-layer circuitry may be required in complex designs. The addition of multiple layers to a DBC wafer is an additive process. For example, the steps may include adding a first conductor layer, adding a dielectric layer, adding a second conductor layer, etc. Accordingly, multi-layer DBC wafer processing may be expensive and may involve many processing steps.

Therefore, it is desirable to have more efficient methods for the manufacturing of heat sink-backed printed circuits, especially for multi-layer circuitry.

### SUMMARY OF INVENTION

In one aspect, embodiments of the invention relate to methods for manufacturing a printed circuit bonded to a heat sink. A method in accordance with one embodiment of the invention includes producing the printed circuit comprising at least one conductive layer circuit pattern laminated to at least one side of a dielectric layer; first adhering a first side of a bond film to the printed circuit, wherein the first adhering conforms the printed circuit to the bond film to substantially remove air entrapment between the printed circuit and the bond film; and second adhering a second side of the bond film to the heat sink, wherein the first adhering and the second adhering bond the heat sink to the printed circuit.

In another aspect, embodiments of the invention relate to methods for manufacturing a printed circuit bonded to a heat sink. A method in accordance with one embodiment of the invention includes producing the printed circuit comprising at least one conductive layer circuit pattern laminated to at least one side of a dielectric layer; stacking a plurality of circuit pre-assemblies, wherein each of the plurality of circuit pre-assemblies comprising a bond film, the printed circuit, conformance materials, and at least one release sheet; first adhering the plurality of circuit pre-assemblies, wherein the first adhering adheres the bond film to the printed circuit in each of the plurality of circuit pre-assemblies to produce a plurality of printed circuit-bond film assemblies; and second adhering a heat sink to each of the printed circuit-bond film assemblies.

In another aspect, embodiments of the invention relates to printed circuits bonded to heat sinks. An apparatus in accordance with one embodiment of the invention includes a printed circuit comprising at least one conductive layer having printed circuit pattern on at least one side of a substrate layer; a heat sink; and a bond film, wherein the bond film laminates the heat sink to the printed circuit, and wherein the bond film is tack-bonded to the printed circuit prior to laminating to the heat sink.

Other aspects and advantages of the invention will be apparent from the following description and the appended claims.

### BRIEF DESCRIPTION OF DRAWINGS

FIG. 1 shows a cross-section view of a printed circuit and bond film before lamination according to one embodiment of the invention.

FIG. 2 shows a cross-section view of a printed circuit and bond film before lamination according to one embodiment of the invention.

FIG. 3 shows a cross-section view of a printed circuit and bond film arranged for lamination according to one embodiment of the invention.

FIG. 4 shows a cross-section view with multiple printed circuits and bond films arranged for lamination according to one embodiment of the invention.

FIG. 5 shows a cross-section view of a printed circuit and bond film after lamination according to one embodiment of the invention.

FIG. 6 shows a cross-section view of a printed circuit bonded to a heat sink according to one embodiment of the invention.

FIG. 7 shows a flow diagram illustrating a manufacturing process for bonding a printed circuit to a heat sink according to one embodiment of the invention.

### DETAILED DESCRIPTION

Embodiments of the present invention relates to a two-step process for mounting a heat sink to a printed circuit, either a flex or a rigid PCB. The first step involves adhering an adhesive bond film to the printed circuit using a relatively low temperature platen press technique. The relatively low temperature is sufficient to “tack-bond” the printed circuit to the bond film, but would not fully cure the adhesive. In this process, the adhesive may be converted into B-stage that still retains the ability to adhere to a heat sink at a higher temperature in the second lamination process. In addition, according to embodiments of the invention, the first lamination is performed in such a way to ensure conformance of the printed circuit panel (e.g., the printed circuit with various layers and/or attached circuits) to the first side of the bond film during the lamination step and to maximize the planarity of the bond film on the second side. Conformance of the printed circuit panels in the first lamination step eliminates or minimizes voids within the composite (or between the printed circuit board and the bond film), while maintaining the planarity of the second side of the bond film facilitates the attachment of the composite to a heat sink in the second lamination process. If the printed circuit board includes multiple circuits, it may be depanelized into individual printed circuits before the second lamination step. While it may be more convenient to depanelize individual panels at this stage, one of ordinary skill in the art would appreciate that it is expressly within the scope of the present invention to defer the depanelization step until after the heat sinks are attached.

In the second step according to one embodiment of the invention, the depanelized printed circuits are bonded to individual heat sinks at relatively high temperature. The higher temperature fully cures the adhesive and ensures tight bonding between the printed circuit and the bond film and between the bond film and the heat sink. In some embodiments, the individual circuits are not depanelized before the second lamination step. Instead, the printed circuit board (including a plurality of individual circuits) are first laminated to the heat sinks and then the individual printed circuits with the heat sinks attached are depanelized.

With a two-step approach, embodiments of the invention provide economical methods for the manufacturing of printed circuits. The pre-assembly of the printed circuit in the first lamination process and the use of the adhesive bond film allow for very fast bond cycles. Once the printed circuit-bond film pre-assembly is available, the second lamination step may be performed by original equipment manufacturers in an economical single-unit production process.

For the purposes of the present invention, bonding, adhering, and laminating may be used to mean an act of sticking one surface or element to another surface or element. Also, a composite is used to mean an element that results from the bonding, adhering, or laminating of two or more surfaces and/or elements.

Furthermore, a printed circuit may include a rigid printed circuit board and/or a flex printed circuit board. For the purposes of the present invention, pressing is generally referred to with respect to a platen press technique. However, one of ordinary skill in the art would appreciate that other similar process may be used without departing from the scope of the present invention.

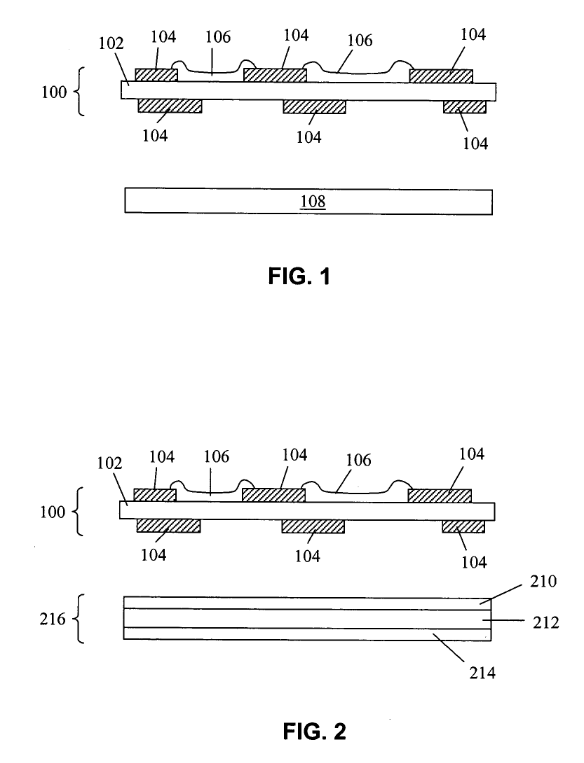

FIG. 1 shows a cross-section view of an exemplary printed circuit (100) and bond film (108) before lamination according to one embodiment of the invention. The exemplary printed circuit (100) includes a substrate/dielectric layer (102) that has a conventionally printed and etched conductive layer circuit pattern (104). The printed circuit (100) also includes, in this example, a solder mask (106) on one side of the printed circuit. One of ordinary skill in the art will understand that the printed circuit in some cases may include a plurality of substrate layers (102), conductive layer circuit patterns (104), and solder masks (106) that are laminated together.

As in a conventional printed circuit, thermal vias (not shown), which are plated-through holes between a top and bottom conductive layer of a printed circuit board, may also be included in the printed circuit (100) where power components will be solder mounted. In addition, thermal transfer through a substrate material (e.g., substrate layer (102)) can be maximized by the use of ceramic-filled and/or very thin dielectric layers.

In FIG. 1, the printed circuit (100) will be bonded to an electrically-isolating, thermally-conductive, adhesive bond film (108). The adhesive bond film may be a homogeneous polymer adhesive sheet (108), with enough physical strength and thickness to endure the lamination processes without excessive flowing and subsequent electrical shorting. Examples of homogeneous polymer adhesive sheets include Kapton™ LJ and KJ polyimide films from E. I. du Pont de Nemours and Company (Wilmington, Del.) and PIXEO™ polyimide film from Kaneka High-Tech Materials, Inc. (Pasadena, Tex.). In some embodiments, the bond film (108) may have ceramic powder filler to maximize thermal transfer, as well as punch-through and flow resistance. Furthermore, the substrate layer (102), solder mask (106), and bond film (108) preferably are robust enough to withstand the lamination processes without allowing shorting between conductors or between the bottom conductor layer and a heat sink (not shown). Conventional substrates, such as those based on dielectric films sold under the trade names of Kapton™ and Mylar™ by E. I. du Pont de Nemours and Company (Wilmington, Del.) or rigid substrates based on fiberglass-reinforced epoxy or polyimide resin, can withstand the lamination processes without electrical shorting.

The exposed conductors on the printed circuit (100), e.g., the conductive layer circuit pattern (104) on the solder mask (106) side of the printed circuit, may need to be treated with an anti-oxidation coating to prevent tarnishing during a laminating cycle and to ensure solderability for the attachment of electronic components. The antioxidant coating may be a polymer (organic antioxidant) coating or metal plating such as tin/lead, gold, etc. The conductive layer circuit pattern (104) on the non-solder mask side (i.e., the bottom side) of the printed circuit is preferably left exposed to facilitate lamination to the bond film (108). Furthermore, some additional functionality may be added to the printed circuit, such as screen-printed resistors or shielding.

FIG. 2 shows a cross-section view of an exemplary printed circuit (100) and bond film (216) before lamination according to another embodiment of the invention. In contrast to the homogeneous bond film (108) shown in FIG. 1, the bond film (216) shown in FIG. 2 comprises adhesives (210, 214) on both sides of a dielectric film (212). The adhesive is preferably thermoplastic in nature. In some embodiments, the adhesive layers 210 and 214 may be of the same material, while in other embodiments, these adhesive layers may be of different materials. If the adhesive layers 210 and 214 are made of different materials, they may be selected such that the conditions required for laminating the first adhesive layer would have minimal effects on the second adhesive layer. The bond film 216 preferably has enough physical strength and thickness to endure the lamination processes without excessive flowing and subsequent electrical shorting. Some or all of the layers (210, 212, and 214) of the adhesive bond film 216 may have ceramic powder filler to maximize thermal transfer, as well as punch-through and flow resistance.

A method in accordance with the present invention uses a two-step lamination process to bond a heat sink to a printed circuit. In FIGS. 1 and 2, the adhesive bond film (108 in FIG. 1 or 216 in FIG. 2) may be adhered to the printed circuit (100) in panel form using a conventional platen press technique and apparatus at a relatively low temperature. The relative low temperature used in this process is sufficient to “tack-bond” the printed circuit to the bond film, but it is not high enough to produce a complete bond. This ensures that the side of the bond film (108 in FIG. 1 or 216 in FIG. 2) away from the printed circuit has residual adhesion for the second lamination process. In accordance with embodiments of the invention, the first lamination process is performed in such a way to ensure conformance of the panel materials during lamination and to maximize the planarity of the bond film on the side of the bond film (108 in FIG. 1 or 216 in FIG. 2) away from the printed circuit. Conformance of the printed circuit (100) to the bond film (108 in FIG. 1 or 216 in FIG. 2) eliminates or minimizes voids within the circuit construction, while maximizing the planarity of the bond film facilitates the second lamination process. If the circuit (100) is laminated in a panel form having a plurality of individual circuits, these individual circuits together with the tack-bonded bond film can be depanelized after the first lamination process. Alternatively, depanelization may be performed after the heat sinks have been attached to the printed circuits in the second lamination step.

As noted above, the temperature and duration of the first lamination process is selected to ensure consistent adhesion of the printed circuit to the bond film (108 in FIG. 1 or 216 in FIG. 2), but allows further reactivity of the adhesive layer on the side of the bond film (108 in FIG. 1 or 216 in FIG. 2) away from the printed circuit. After the first lamination step, the printed circuit (100) is bonded to the bond film (108 or 216) with a sufficient strength to withstand subsequent processing (e.g., depanelization), but not fully bonded. This state is referred to as “tack-bond.” One of ordinary skill in the art would appreciate that the adhesive is probably in a B-stage after the first lamination. The precise temperature, pressure, and duration for achieving the tack-bond depends on the particular material used. For example, with a thermoplastic polyimide adhesive, the tack-bond may be achieved with a temperature of 160-190° C., a pressure of 50-1000 psi, and a duration of 1-180 seconds.

The first lamination process may be performed with high pressure in a conventional platen press that provides considerably greater conformance from the top side than from the bottom side in order to eliminate or reduce air entrapment (voids) and to maximize circuit planarity on the bottom side of the bond film (108 in FIG. 1 or 216 in FIG. 2), i.e., the side away from the printed circuit.

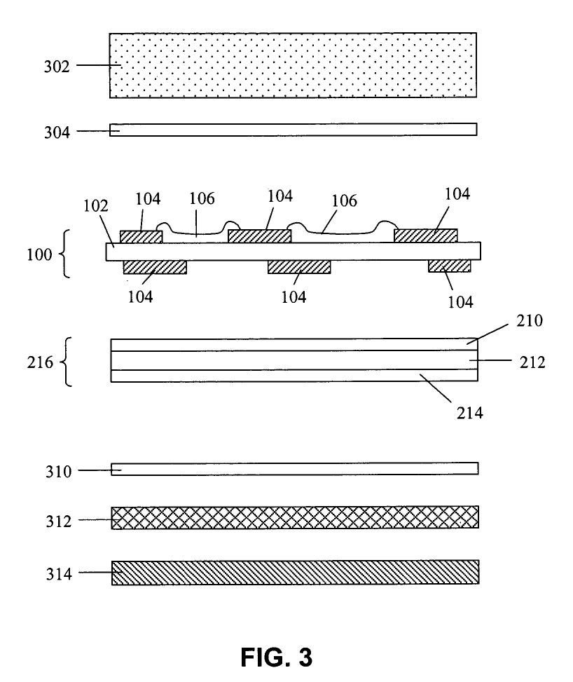

FIG. 3 illustrates a method in accordance with embodiments of the invention for laminating a printed circuit (100) to a bond film (216). As shown, the printed circuit (100) and the bond film (216) are arranged for lamination by stacking the printed circuit (100) and adhesive bond film (216) with additional elements, including release sheets (304, 310) that allow the laminated printed circuit (100) and adhesive bond film (216) to be removed intact after lamination, and a high conformance material (302) and a low conformance material (312) that substantially spread the pressure caused by platen pressing evenly over a surface. The release sheets suitable for this purpose may include sheets made of materials that will not stick to the printed circuit (100) or the bond film (108 or 216). Such materials, for example, may include skived or extruded Teflon™ film, Teflon™-coated glass cloth. A high conformance material suitable for this purpose, for example, may be selected from rubber-coated glass cloth, Pacoform conformable paper from Pacothane Technologies (New York, N.Y.), and the like, and a low conformance material suitable for this purpose, for example, may be selected from cardboard, hard rubber, and the like.

The stack or lay-up shown in FIG. 3 may use an aluminum plate on the top as well as the bottom, for example aluminum plate (314), to apply pressure to the stack. In operation, the top and bottom aluminum plates (platens) apply a selected pressure to the conformance materials while the assembly is heated at a selected temperature for a selected period of time. As noted above, the selected pressure, temperature, and duration would depend on the bond film material and the complexity of the assembly.

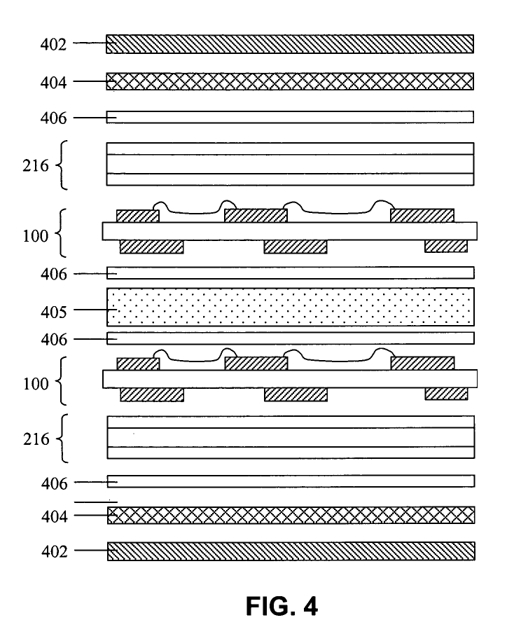

While the method illustrated in FIG. 3 is for a single panel lamination, embodiments of the invention may also be used in simultaneous, multiple panel lamination. FIG. 4 illustrate a method in accordance with one embodiment of the invention for simultaneously laminating multiple printed circuit panels. To facilitate large scale production, a stack or lay-up in a single press cycle may include many printed circuits and bond film laminations. Stacking multiple printed circuits and bond films saves both process time and process materials. As shown in FIG. 4, multiple printed circuits (100) and adhesive bond films (216) are arranged for lamination by stacking the multiple printed circuits (100) and adhesive bond films (216) with additional elements, including release sheets (406) that allow the laminated printed circuit and adhesive bond film to be removed intact after lamination and a high conformance material (405) and a low conformance material (404) that substantially spread the pressure caused by platen pressing evenly over a surface. The stack or lay-up shown in FIG. 4 may use an aluminum plate (402) on the top as well as the bottom to apply pressure to the stack.

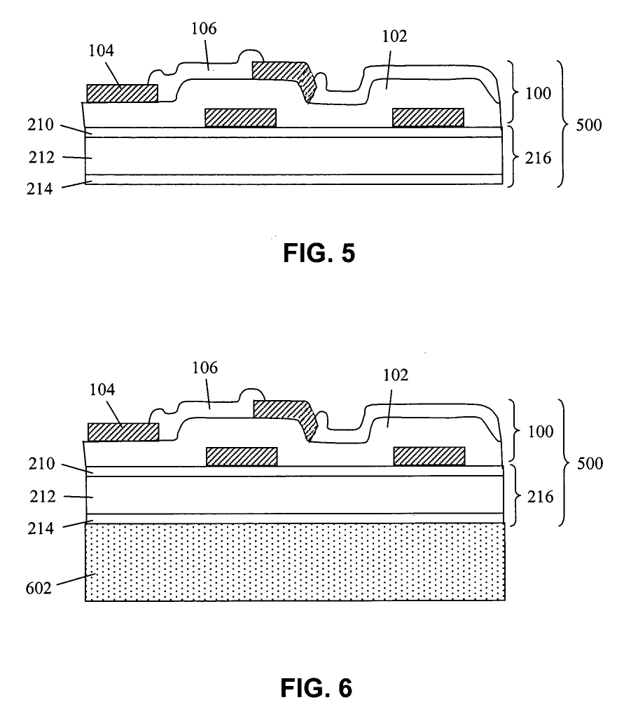

By conforming the printed circuit to the bond film from the top side as illustrated in FIGS. 3-4, methods of the invention eliminate or reduce air entrapments (voids) in the printed circuit-bond film assembly. Reducing the voids in the assembly enhances thermal transfer through the bond film and maximizes dielectric reliability. In addition, the methods of the invention maximize the planarity of the bond film on the side that is to be laminated to a heat sink. Such a planar surface facilitates the lamination of the circuit-bond film assembly to a heat sink and reduces the possibility of voids between the bond film and the heat sink. FIG. 5 shows a cross-section view of an exemplary printed circuit-bond film assembly (500) after lamination according to one embodiment of the invention. As shown, the assembly (500) has the printed circuit (100) conforming to the flat surface of the bond film (216) from the top side such that there is no or minimal air entrapment between the printed circuit (100) and the bond film (216). In addition, by conforming the printed circuit (100) from the top side, the bottom surface of the bond film (216) in the assembly (500) is essentially flat. The flat surface of the bond film (216) will facilitate the lamination of the assembly (500) to a heat sink. As noted above, after the bond film is laminated to the printed circuit, if the laminated circuit panel includes a plurality of individual circuits, it may be depanelized by punching or routing. Alternatively, the depanelization may be performed after the heat sinks have been attached.

After the first lamination, the assembly (500) shown in FIG. 5 is ready to be laminated to a heat sink. FIG. 6 shows a cross-section view of an exemplary printed circuit-bond film assembly (500) bonded to a heat sink (602) according to one embodiment of the invention. This second lamination step is typically performed at a higher temperature than that used in the first lamination. A typical condition for the second lamination, for example, may involve a temperature of 220-300° C., a pressure or 50-1000 psi, and a duration of 10-200 seconds. One of ordinary skill in the art would appreciate that the optimal temperature, pressure, and duration of this process depend on the materials in the bond film and the complexity of the printed circuit-bond film assembly. In a preferred embodiment, a partially thermoplastic resin is used in the bond film. The thermoplastic nature of the adhesive allows fast bonding and facilitates efficient single unit manufacturing.

In FIG. 6, conforming the printed circuit from the side with the printed circuit (e.g., top side) eliminates air voiding and ensures planarity of the side away from the printed circuit. However, non-flat copper mounting sites for electronic components can result from this process (See FIG. 6). The solder paste that is added to the printed circuit to attach electronic components, typically by screen-printing, may compensate for any top side non-planarity.

Flexible circuits may have areas which are not laminated to the heat sink (602). The un-laminated circuit area allows for interconnection with other areas of the total electronic assembly (such as between layers of a power converter) or between heat sinks (602) in a folded assembly.

According to some embodiments of the invention, the second lamination may be performed with a heat sink (602) that has been primed with a thin layer of adhesive coating (i.e., a primer coating, thickness from about 0.1 to about 2 microns) that allows the circuit to be bonded to the heat sink (602) at a lower temperature than would otherwise be required. For example, the required bonding temperature might drop from 300° C. to 250° C. with use of the heat sink (602) priming. The thin layer of adhesive coating (i.e., primer coating) facilitates the second lamination process and reduces the incident of damage—due to the lower bonding temperature—to the solder mask (106) and minimizes the oxidation of the top side of copper surface (e.g., conductive layer circuit pattern (104) on the solder mask (106) side of the printed circuit) that will be soldered.

The heat sink (602) used in the second lamination, according to embodiments of the invention, need not be planar. Instead, these heat sinks (602) may have fins or walls (e.g., in a box shape). Furthermore, the heat sink (602) can be of any thickness or material that can withstand the circuit bonding process.

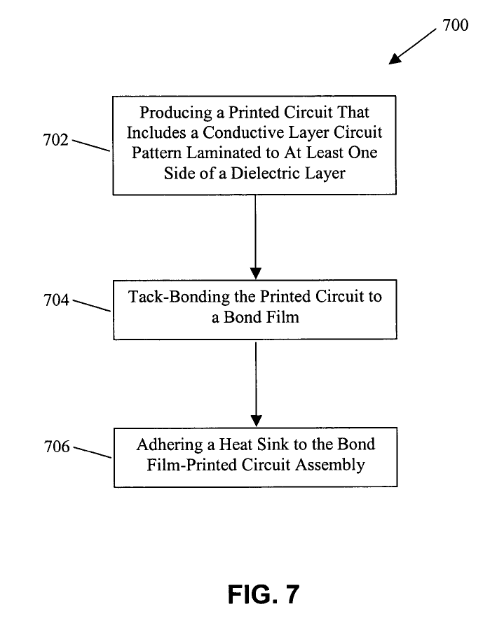

FIG. 7 shows a flow diagram illustrating a manufacturing process (700) for bonding a printed circuit to a heat sink according to one embodiment of the invention. In step 702, a printed circuit board is produced, which includes at least one conductive layer circuit pattern laminated to at least one side of a dielectric layer. The printed circuit may use conventional printed circuit manufacturing processes. The printed circuit may use a rigid or flexible circuit substrate.

One embodiment of the present invention uses a two-step process to bond a heat sink to a printed circuit. In step 704, a first surface of an adhesive bond film is pressed to a printed circuit. The bond film may be a homogenous bond film (e.g., 108 in FIG. 1) or a composite bond film having two adhesive layers coated on a dielectric layer (e.g., 216 in FIG. 2). As noted above, in this first lamination step, the printed circuit is forced from the top side to conform to the bond film such that air entrapment is minimized or eliminated and the second side of the bond film retains planarity. Even at high pressure, the first lamination process does not overflow the bond film, which could lead to dielectric shorting in a homogeneous bond film. The first lamination process takes no more than a few minutes and is designed for conventional platen presses, which might have a maximum temperature of 180-250° C. After the first lamination process, the circuits can undergo further processing, if necessary, and then be depanelized.

In step 706, a heat sink is adhered to the second surface of the bond film such that the heat sink is bonded to the printed circuit using a high temperature process. The circuit board and the bond film have already been laminated in the first lamination process in such a way to eliminate air voiding and to maximize planarity of the bond film on the side away from the circuit board. The printed circuit-bond film assembly can then be bonded at high temperature and high pressure to the heat sink. The heat-sealing nature of the thermoplastic adhesive bond film allows fast, single unit production with a cycle time that may take only 10-200 seconds, depending on the material of the bond film and the size and complexity of the assembly.

Advantages of the present invention may include one or more of the following. In one or more embodiments, this invention provides multi-layer printed circuits to be mounted to heat sinks with high thermal transfer from the electronic components and conductors to the heat sink. The invention uses conventional circuit board materials, designs, and processes. It is preferable over the existing technologies of IMS and DBC in cost, performance, and design flexibility.

In one or more embodiments, higher thermal transfer than conventional mounting methods of flex and rigid printed circuit boards to heat sinks at comparable cost is achieved. The thermal resistance of the present invention from the heat producing electronic components and conductors on the circuit board to the heat sink is a fraction of the thermal resistance of conventional mounting methods, which include various tapes and adhesive sheets. Better thermal transfer can provide one, or a combination, of the following performance advantages: lower electronic component temperatures hereby increasing reliability, reduction in component and/or heat sink rating and cost that allows less expensive devices and/or heat sinks to be used, and an increase in output from a similar system, e.g., more output Wattage from similar power supply unit.

With embodiments of the invention, printed circuit boards are pressed against heat sinks with electrically insulating and thermally conductive interface material between the printed circuit board and the metal heat sink. No special assembly equipment is required. In addition, while IMS and DBC constructions also need to be mechanically attached to a heat sink with a thermally conductive interface material between the IMS or DBC and the heat sink, the printed circuit construction described in the present invention is bonded directly to the heat sink with a thermally activated adhesive.

The present invention can achieve a lower cost than IMS and DBC ceramic constructions. IMS and DBC use expensive materials and processes that have limited availability. This invention uses conventional materials and processes that are widely-available.

The present invention has a greater design flexibility than IMS and DBC constructions. Both IMS and DBC technologies are based on flat plates, requiring all circuitry and components to be on one plane only. Circuitry can only extend to the edge of the planar substrate (metal sheet in IMS, ceramic wafer in DBC). Adding multiple conductor layers is an expensive process in both IMS and DBC. DBC is also very brittle and has a limited process size (maximum of 4 inches by 4 inches). The present invention has significant design advantages over IMS and DBC in that it can produce thermal management assemblies that are physically flexible (plastic film dielectric), can be bonded directly to practically any shape or size or material type heat sink (assuming that the heat sink can withstand the lamination process), allows circuitry to extend past the edge of the heat sink (perhaps connecting to other subassemblies), uses conventional circuit processing equipment and materials, is physically robust by using “unbrittle” plastic film dielectric and metal heat sink, and can be made into literally any dimension (width or length).

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. A method for manufacturing a printed circuit bonded to a heat sink, comprising:
producing the printed circuit comprising at least one conductive layer circuit pattern laminated to at least one side of a dielectric layer;
first adhering a first side of a bond film to the printed circuit, wherein the first adhering conforms the printed circuit to the bond film to substantially remove air entrapment between the printed circuit and the bond film; and
second adhering a second side of the bond film to the heat sink.

2. The method of claim 1, wherein the first adhering is performed at a lower temperature than the second adhering.

3. The method of claim 1, wherein the first adhering forms a tack bond between the printed circuit and the bond film.

4. The method of claim 1, wherein the heat sink is primed with a primer coating of adhesive before the second adhering.

5. The method of claim 4, wherein the primer coating has a thickness in a range of about 0.1 to about 2 microns.

6. The method of claim 1, wherein the first adhering is performed with a platen press.

7. The method of claim 1, wherein the bond film is a thermoplastic resin film.

8. The method of claim 1, wherein the bond film is a composite film comprising two adhesive layers and a dielectric layer.

9. The method of claim 8, wherein the two adhesive layers on the bond film are made of different adhesive materials.

10. The method of claim 1, wherein the bond film includes ceramic powder filler.

11. The method of claim 1, wherein the printed circuit comprises a plurality of individual circuits.

12. The method of claim 11, further comprising depanelizing the plurality of individual circuits before the second adhering.

13. A method for manufacturing a printed circuit bonded to a heat sink, comprising:
producing the printed circuit comprising at least one conductive layer circuit pattern laminated to at least one side of a dielectric layer;
stacking a plurality of circuit pre-assemblies, wherein each of the plurality of circuit pre-assemblies comprising a bond film, the printed circuit, conformance materials, and at least one release sheet;
first adhering the plurality of circuit pre-assemblies, wherein the first adhering adheres the bond film to the printed circuit in each of the plurality of circuit pre-assemblies to produce a plurality of printed circuit-bond film assemblies; and
second adhering a heat sink to each of the printed circuit-bond film assemblies.

14. The method of claim 13, wherein the first adhering uses a platen press.

15. The method of claim 13, wherein the first adhering is performed at a lower temperature than the second adhering to the heat sink.

16. The method of claim 13, wherein the first adhering produces a tack bond between the printed circuit and the bond film.

17. The method of claim 13, wherein the heat sink is primed with a primer coating of adhesive before the second adhering.

18. The method of claim 17, wherein the primer coating has a thickness in a range of about 0.1 to about 2 microns.

19. The method of claim 13, wherein the first adhering uses at least one plate to press the plurality of elements.

20. The method of claim 13, wherein the bond film is a thermoplastic resin film.

21. The method of claim 13, wherein the bond film is a composite film comprising two adhesive layers and a dielectric layer.

22. The method of claim 21, wherein the two adhesive layers on the bond film are made of different adhesive materials.

23. The method of claim 12, wherein the bond film includes ceramic powder filler.

24. An apparatus, comprising:
a printed circuit comprising at least one conductive layer circuit pattern laminated to at least one side of a dielectric layer;
a heat sink; and
a bond film, wherein the bond film laminates the heat sink to the printed circuit, and wherein the bond film is tack-bonded to the printed circuit prior to laminating to the heat sink.
